(19) United States
(12) Patent Application Publication
(10) Pub. No.: US 2014/0360863 A1
(43) Pub. Date: Dec. 11, 2014

(54) SrRuO3 FILM DEPOSITION METHOD

(71) Applicant: CANON ANELVA CORPORATION, Kawasaki-shi (JP)

(72) Inventors: Yoshiaki DAIGO, Kawasaki-shi (JP); Keiji ISHIBASHI, Kawasaki-shi (JP)

(21) Appl. No.: 14/310,099

(22) Filed: Jun. 20, 2014

Related U.S. Application Data
(63) Continuation of application No. PCT/JP2012/008039, filed on Dec. 17, 2012.

(30) Foreign Application Priority Data
Dec. 22, 2011 (JP) 2011-281206

(51) Int. Cl. C23C 14/08; C23C 14/35

(52) U.S. Cl. CPC C23C 14/088; C23C 14/35
USPC 204/192.22

(57) ABSTRACT

The present invention provides a SrRuO₃ film manufacturing method capable of depositing high-quality SrRuO₃ film while achieving a high deposition rate and preventing occurrence of abnormal discharge in the process of depositing the SrRuO₃ film by DC magnetron sputtering. An embodiment of the present invention is a SrRuO₃ film deposition method by offset rotary deposition-type DC magnetron sputtering, which includes depositing SrRuO₃ film on a substrate at a deposition pressure of 1.0 Pa or more and less than 8.0 Pa in an oxygen-containing atmosphere.

### CROSS-REFERENCES TO RELATED APPLICATIONS

This application is a continuation application of International Application No. PCT/JP2012/008039, filed Dec. 17, 2012, which claims the benefit of Japanese Patent Application No. 2011-281206, filed Dec. 22, 2011. The contents of the aforementioned applications are incorporated herein by reference in their entireties.

### TECHNICAL FIELD

The present invention relates to a SrRuO₃ film manufacturing method, and more specifically relates to a SrRuO₃ film manufacturing method of depositing SrRuO₃ film by DC magnetron sputtering.

### BACKGROUND ART

Strontium ruthenate (SrRuO₃) is a conductor with a perovskite structure having high thermal and chemical stabilities and a low resistivity. SrRuO₃ is therefore expected as an electrode material for ferroelectric devices, piezoelectric devices, magnetoresistive devices, superconducting devices, and other similar devices. For example, conventional ferromagnetic nonvolatile memories (FeRAM) have used platinum (Pt) for the electrode material of ferroelectric capacitors. However, in recent years, it has been examined to insert SrRuO₃ film at the interface between the ferromagnetic film and Pt film for the purpose of preventing degradation of the device characteristics. Moreover, in recent years, ferromagnetic recording-type ultra-high recording density storages have been expected to replace magnetic recording hard disks (HDs), and SrRuO₃ has been examined as the electrode material thereof. As described above, SrRuO₃ is a material that is attracting a lot of attention as the electrode material for various types of functional devices.

As the method of depositing SrRuO₃ film described above, MOCVD, pulse laser deposition, molecular beam epitaxy, and sputtering are being examined. The MOCVD is excellent in productivity, including the growth rate, an increase in substrate area, and the like, but has problems such as low reproducibility and high production cost. On the other hand, the pulse laser deposition and molecular beam epitaxy have a problem of low productivity including the growth rate, an increase in substrate area and the like. In the light of industrial mass-production, there is demand for sputtering which can provide stable reproducibility, low production cost, and relatively good productivity including the growth rate, an increase in substrate area and the like.

Patent Document 1 discloses a method of manufacturing SrRuO₃ film using sputtering as described above. FIG. 7 is a schematic configuration view of a sputtering apparatus according to Patent Document 1. A substrate 702 and a target 703 are placed to face each other in a vacuum vessel 701. The substrate 702 is attached to a heater 704 and is connected to a power supply 705. The target 703 is also connected to a power supply 706. The power supply may be either a radio frequency (RF) power supply or direct-current (DC) power supply. The vacuum vessel 701 is evacuated by a vacuum pump 707 composed of a turbo-molecular pump, a rotary pump, and other parts. On the other hand, atmospheric gas is introduced via the vacuum vessel 701 from cylinders 708 and 709 (an oxygen cylinder 708 and an argon cylinder 709, for example) via a flow-rate meter 710, and the inside of the vacuum vessel 701 is set at oxygen-containing gas atmosphere.

Patent Document 1 discloses that high-quality SrRuO₃ film can be obtained at a comparatively high deposition rate by normal static target-facing type sputtering (as illustrated in FIG. 7) with a deposition pressure of 8.0 Pa or more and less than 300 Pa. In the description of Patent Document 1, the reason for using such a comparatively high deposition pressure is to reduce acceleration of high energy particles (plasma particles in Patent Document 1) and thereby avoid damage to the SrRuO₃ film. Furthermore, Patent Document 1 states that the conditions other than the deposition pressure hardly influence the quality of the produced SrRuO₃ film. In the description thereof, for example, the ratio of inert gas used as process gas to an oxygen-giving substance such as oxygen gas may be 1:1 to 10:1, the substrate temperature may be set in a range from 450 to 650° C., and the power supply for sputtering may be either a direct-current power supply or an alternating-current power supply. Furthermore, Patent Document 1 states that the target can be a SrRuO₃ target, a composite target of strontium carbide (SrCO₃) and ruthenium oxide (RuO₂), or the like.

The invention described in Patent Document 1 is an invention aimed to improve the quality of SrRuO₃ film while achieving a comparatively high deposition rate and avoiding damage to the SrRuO₃ film due to high-energy particles, by using normal static target-facing type sputtering and by setting the deposition pressure to a comparatively high pressure of 8.0 or more and less than 300 Pa.

On the other hand, Patent Document 2 discloses a functional oxide structure and a method of manufacturing the same. The functional oxide structure includes a substrate A made of monocrystal Si, a conductive perovskite oxide thin film B which is made of XRuO₃ (X is at least one kind of alkaline-earth metal) and laid on the substrate A as a thin film B layer, and a ferroelectric thin film C which is composed of PbZOₙ (where Z is at least one element selected from La, Zr, Ti, Nd, Sm, Y, Bi, Ta, W, Sb, and Sn) and is laid on the thin film B as a thin film C layer. FIG. 8 is a schematic view of a functional oxide structure manufacturing apparatus described in Patent Document 2. The apparatus described in Patent Document 2 is an RF magnetron sputtering film deposition apparatus including two targets. Reference numeral 821 indicates a target of a conductive oxide SrRuO₃ composition, and reference numeral 822 indicates a Pb(Ti, Zr)O₃ target for depositing a ferroelectric thin film. As for the formation of the thin film B and C layers, Patent Document 2 describes the following deposition method. Specifically, first, a monocrystal Si substrate 823 is heated to 660° C. by a heater 824, and a SrRuO₃ target 821 is selected by a shutter 825. Then, plasma is generated by radio-frequency waves to deposit the thin film B layer to 300 nm. The shutter 825 is then closed, and the substrate temperature is reset to 400° C. by the heater 824. Thereafter, the target 822 for ferroelectric oxide Pb(Ti, Zr)O₃ is selected by the shutter 825 to deposit the thin film C layer to 1000 nm.

### PRIOR ART DOCUMENTS

### Patent Documents

Patent Document 1: Japanese Patent Application Laid-Open No. 2008-240040

Patent Document 2: Japanese Patent Application Laid-Open No. Hei 07-223806

### SUMMARY OF INVENTION

However, the inventor's experiments to verify the invention described in Patent Document 1 revealed that Patent Document 1 includes the following problems.

To be specific, the inventors performed experiments to verify Patent Document 1 using a normal static target-facing type sputtering apparatus (magnetron sputtering apparatus) illustrated in FIG. 9. In the drawing, reference numeral 901 indicates a vacuum vessel; 902, a chamber shield; 905, a substrate holder; 907, a target; 908, a cathode; 909, a magnet unit; 910, a power supply; 911, a gas source; 912, a vacuum pump; 913, a substrate; and 914, a tray. In this verification experiments, the power supply for sputtering was a DC power supply, and the target was a SrRuO₃ target. The inventors formed SrRuO₃ film by using the aforementioned DC magnetron sputtering and confirmed that high-quality SrRuO₃ film was obtained at a comparatively high deposition rate with a deposition pressure of 8.0 Pa or more as described in Patent Document 1. However, with such a comparatively high deposition pressure, abnormal discharge is more likely to occur, and it was difficult to prevent the occurrence of abnormal discharge at least in the condition ranges disclosed in Patent Document 1. The abnormal discharge serves as a source of particles, and it is difficult to manufacture devices including SrRuO₃ film at a high yield.

As described above, Patent Document 1 is an invention which uses the normal static target-facing type sputtering aimed to improve the quality of SrRuO₃ film while achieving a comparatively high deposition rate, but discloses nothing at all about a method of preventing the aforementioned abnormal discharge. To put it differently, it is difficult to intentionally prevent the aforementioned abnormal discharge only by the invention disclosed in Patent Document 1, and the abnormal discharge remains as a significant problem in the production of devices including SrRuO₃ film.

On the other hand, the manufacturing apparatus described in Patent Document 2 is not configured to rotate the substrate 823 for deposition, and therefore has a problem of being incapable of depositing SrRuO₃ film on the substrate to a uniform thickness. Moreover, Patent Document 2 discloses a manufacturing method which employs multi-target RF magnetron sputtering using conductive oxide SrRuO₃. However, Patent Document 2 does not disclose or suggest a manufacturing method which employs multi-target DC magnetron sputtering using conductive oxide SrRuO₃ and has a problem that the manufacturing apparatus does not include means for inhibiting abnormal discharge caused in DC magnetron sputtering.

The present invention was made in the light of the aforementioned problems, and an object of the present invention is to provide a SrRuO₃ film manufacturing method which is capable of depositing high-quality SrRuO₃ film at a high deposition rate while preventing occurrence of abnormal discharge in the process of depositing the SrRuO₃ film by DC magnetron sputtering.

As a result of intensive research and studies, the inventors completed the present invention by obtaining new findings that in the case of depositing SrRuO₃ film by sputtering, especially, by DC magnetron sputtering, it is possible to obtain high-quality SrRuO₃ film at a high deposition rate while preventing abnormal discharge by using offset rotary deposition-type DC magnetron sputtering and by setting the pressure of the oxygen-containing atmosphere for depositing the SrRuO₃ film by the DC magnetron sputtering to 1.0 Pa or more and less than 8.0 Pa, as will be described later.

In order to achieve the aforementioned object, an aspect of the present invention is a SrRuO₃ film deposition method by offset rotary deposition-type DC magnetron sputtering, the method including depositing the SrRuO₃ film on a substrate at a deposition pressure of 1.0 Pa or more and less than 8.0 Pa in an oxygen-containing atmosphere.

According to the present invention, by using DC magnetron sputtering which can reduce the apparatus cost compared with sputtering using other types of power supply, it is possible to improve the quality of SrRuO₃ film while achieving a comparatively high deposition rate and preventing occurrence of abnormal discharge.

### BRIEF DESCRIPTION OF DRAWINGS

FIG. 1 is a schematic configuration view of a film deposition apparatus for SrRuO₃ film according to an embodiment of the present invention.

FIG. 2A is a schematic configuration view of an offset rotary deposition-type magnetron sputtering apparatus for depositing SrRuO₃ film according to the embodiment of the present invention.

FIG. 2B is a schematic configuration view of the offset rotary deposition-type magnetron sputtering apparatus for depositing SrRuO₃ film according to the embodiment of the present invention.

FIG. 3 is a diagram showing an X-ray diffraction pattern (2θ/ω scan mode) of SrRuO₃ film formed by a method according to the embodiment of the present invention.

FIG. 4 is a diagram showing an X-ray diffraction pattern (φ scan mode) of the SrRuO₃ film formed by the method according to the embodiment of the present invention.

FIG. 5 is a diagram showing a reciprocal lattice map of the SrRuO₃ film formed by the method according to the embodiment of the present invention.

FIG. 6 is a view illustrating a cross-sectional profile of a SrRuO₃ target according to the embodiment of the present invention.

FIG. 7 is a schematic view of a sputtering apparatus according to Patent Document 1.

FIG. 8 is a schematic view of a functional oxide structure manufacturing apparatus according to Patent Document 2.

FIG. 9 is a schematic configuration view of a sputtering apparatus that the inventors used in a comparative experiment of Patent Document 1.

FIG. 10 is a view for explaining the effect of offset rotary deposition-type DC magnetron sputtering according to the embodiment of the present invention.

FIG. 11 is a view for explaining the effect of the offset rotary deposition-type DC magnetron sputtering according to the embodiment of the present invention.

FIG. 12 is a view for explaining the effect of the offset rotary deposition-type DC magnetron sputtering according to the embodiment of the present invention.

FIG. 13 is a view for explaining the offset position according to the embodiment of the present invention.

### DESCRIPTION OF EMBODIMENTS

Hereinafter, a description is given of embodiments of the present invention in detail with reference to the drawings. In the drawings described below, the portions having the same function are given the same reference numeral, and the same description thereof is omitted.

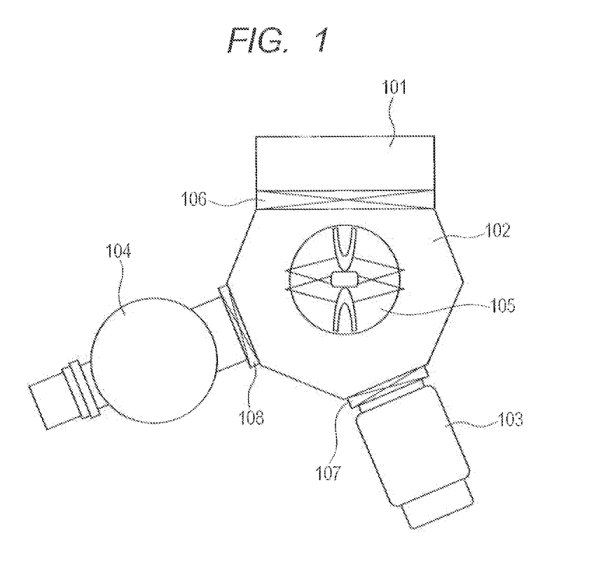

FIG. 1 is a schematic configuration view of a SrRuO₃ film deposition apparatus for according to an embodiment of the present invention. In the drawing, reference numeral 101 indicates a load lock chamber; 102, a conveyance chamber; 103, a pretreatment chamber; 104, a sputtering chamber; 105, a conveyance robot; and 106 to 108, gate valves.

The load lock chamber 101, conveyance chamber 102, pretreatment chamber 103, and sputtering chamber 104 are vacuum vessels which individually include independent evacuation means. The load lock chamber 101, pretreatment chamber 103, and sputtering chamber 104 are connected to the conveyance chamber 102 through the gate valves 106, 107, and 108, respectively. The gate valves 106 to 108 are always closed except the time when the substrate is conveyed, so that the load lock chamber 101, conveyance chamber 102, pretreatment chamber 103, and sputtering chamber 104 are independently in a vacuum state.

Hereinafter, a description is given of a method of forming SrRuO₃ film by using the SrRuO₃ film deposition apparatus according to the embodiment of the present invention in detail with reference to FIG. 1.

First, a substrate on which SrRuO₃ film is to be deposited is introduced into the load lock chamber 101 which is at atmospheric pressure, and the load lock chamber 101 is then evacuated to a predetermined pressure by the aforementioned independent evacuation means. Next, the conveyance robot 105 carries the substrate to the conveyance chamber 102 in vacuum through the gate valve 106 and then conveys the substrate to the pretreatment chamber 103 in vacuum through the gate valve 107. Thereafter, the substrate conveyed to the pretreatment chamber 103 is subjected to a predetermined pretreatment. The pretreatment method needs to be properly set depending on the selected substrate (the substrate on which SrRuO₃ film is to be deposited).

In the case of using a strontium titanate (SrTiO₃) substrate, for example, the substrate temperature may be raised to 500° C. or higher to remove water molecules and the like adsorbed to the surface thereof. Such pre-heating can reduce water molecules imported into the sputtering chamber 104 described later and therefore easily implement a stable process. The aforementioned heat treatment is desirable especially in the case of conveying the substrate on a tray because a lot of water molecules are often adsorbed on the tray. Certainly, the above pretreatment process is not limited to the SrTiO₃ substrate and can be used for other substrates.

It is known that oxygen atoms in the surface of a SrTiO₃ substrate tend to be missing when the SrTiO₃ substrate is heated at high temperature. Accordingly, the aforementioned pre-heating may be performed while oxygen gas is introduced into the pretreatment chamber 103 in order to prevent the oxygen atoms in the surface of the SrTiO₃ from becoming easily missing.

In the case of using a Si substrate as the substrate, in the pretreatment chamber 103, the surface of the Si substrate is flattened; an oxide film in the surface of the Si substrate is removed; or an oxide film is formed in the surface of the Si substrate. To flatten the surface of the Si substrate or remove the oxide film in the surface of the Si substrate, the substrate temperature is increased to 850° C. or higher in vacuum, for example. As another method to remove oxide film in the surface of the Si substrate, the oxide film may be chemically removed using active gas or the like. To form oxide film in the surface of the Si substrate, it is possible to employ a method of heating the Si substrate in oxygen-containing gas.

In the case of using the Si substrate as the substrate, it is sometimes necessary to form an underlayer between the SrRuO₃ film and Si substrate additionally, the underlayer being made of a different material from the materials for the SrRuO₃ film and Si substrate. In this case, the pretreatment chamber 103 may be used as a deposition apparatus for forming the underlayer. Representative examples of the candidate for the underlayer are titanium (Ti), Pt, and SrTiO₃, for example. The method of depositing the underlayer is not particularly limited, and a method preferable for deposition of the underlayer can be selected from vacuum deposition, sputtering, MOCVD, MBE, and the like.

The pretreatment in the pretreatment chamber 103 is not always composed of a single process and may be composed of a series of processes including the aforementioned pre-heating, flattening, oxide film formation/removal, underlayer formation processes. In the case of using a SrTiO₃ substrate, for example, the pre-heating is performed in the pretreatment chamber 103 by introducing oxygen gas thereinto as previously described, another pretreatment process to homoepitaxially grow SrTiO₃ film may be performed in the pretreatment chamber 103. This pretreatment can reduce defects existing in the surface of the SrTiO₃ substrate and further increase the crystallinity of the SrRuO₃ film formed later. Moreover, in the case of using a Si substrate, the flattening process may be followed by an oxidation process and may be further followed by a process of forming Pt/Ti laminate film.

After the pretreatment is performed in the pretreatment chamber 103, the substrate is taken out of the pretreatment chamber 103 through the gate valve 107 using the conveyance robot 105 and is then conveyed to the sputtering chamber 104 in vacuum through the gate valve 108. Eventually, in the sputtering chamber 104, the substrate is subjected to film deposition by sputtering under predetermined conditions, so that SrRuO₃ film is formed on the substrate.

The process performed in the sputtering chamber 104 only needs to include at least a process of depositing SrRuO₃ film. The aforementioned pretreatment (including the preheating, flattening, oxide film formation/removal, underlayer formation processes) can be performed in the sputtering chamber 104. For example, the substrate temperature may be set to a preheating temperature as a pretreatment in the sputtering chamber 104 before SrRuO₃ film is deposited in the sputtering chamber 104. Moreover, formation of oxide film may be performed in the sputtering chamber 104 as a pretreatment followed by formation of the base film in the sputtering chamber 104 before the SrRuO₃ film is eventually deposited in the sputtering chamber 104. To perform the process of forming the base film in the sputtering chamber 104, the sputtering chamber 104 needs to include at least a target for depositing SrRuO₃ film and a target for depositing the base film.

In this embodiment, the film deposition apparatus illustrated in FIG. 1 is an example which can stably provide SrRuO₃ film with good productivity, and the conveyance chamber 102 and pretreatment chamber 103 are not necessarily provided in some cases. The processes from the aforementioned pretreatment to deposition of SrRuO₃ film may be performed in the sputtering chamber 104 if there is no significant problem on the processes, for example. In this case, the load lock chamber 101 and sputtering chamber 104 are directly connected through a gate valve. This eliminates the need for installation of the conveyance chamber 102 and the pretreatment chamber 103, thus considerably reducing the apparatus cost. Moreover, when the pretreatment process includes a series of plural processes, it is possible to further provide pretreatment chambers 103 depending on the number of processes. For example, the aforementioned pre-heating, flattening, oxide film formation, and base film formation processes can be performed in different pretreatment chambers 103. Some of the processes are greatly different in temperature conditions, and repeatedly raising and lowering the substrate temperature in the single pretreatment chamber 103 makes it difficult to provide a high productivity. In this case, the plural pretreatment chambers 103 are used. By performing the processes in the respective plural pretreatment chambers 103, it is possible to shorten the time between the processes and thereby considerably increase the productivity.

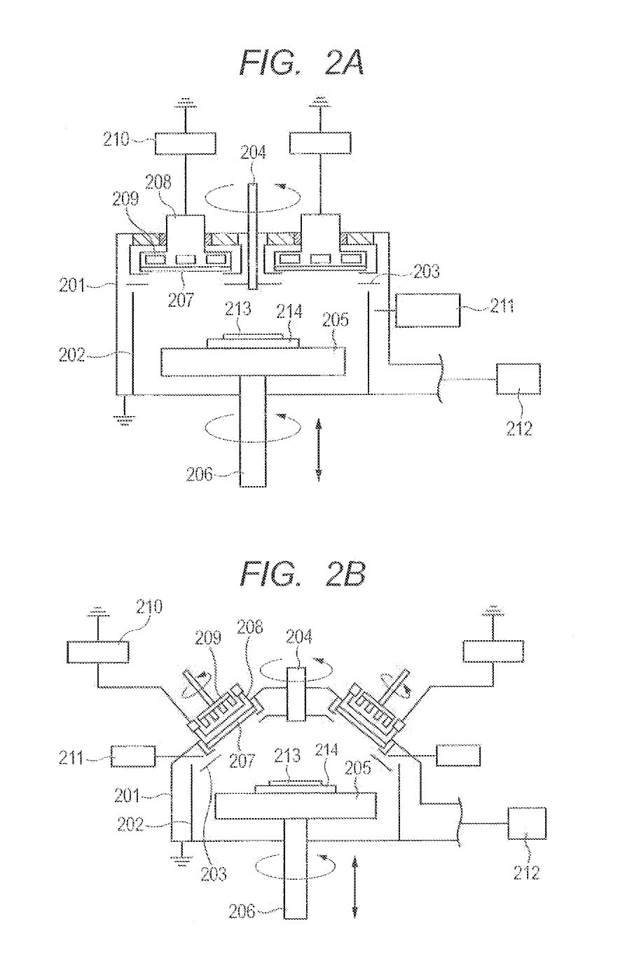

FIGS. 2A and 2B are schematic configuration views of an example of an offset rotary deposition-type magnetron sputtering apparatus for depositing SrRuO₃ film according to the embodiment of the present invention. FIG. 2A is a view illustrating a normal offset rotary deposition-type magnetron sputtering apparatus in which the center position of the substrate holder is away from the center position of the target in the horizontal direction (hereinafter, to be offset) and the normal direction of the substrate holder is positioned in parallel to the normal direction of the target. FIG. 2B is a view illustrating an inclined rotary deposition-type magnetron sputtering apparatus in which the center position of the substrate holder is offset from the center position of the target and the normal direction of the substrate holder and the normal direction of the target are arranged at an angle of more than 0 and less than 90 degrees. In the drawings, reference numeral 201 indicates a vacuum vessel; 202, a chamber shield; 203, a rotary shutter; 204, a rotation mechanism for the rotary shutter; 205, a substrate holder; 206, a up-down rotation mechanism for the substrate holder; 207, targets; 208, cathodes; 209, a magnet unit; 210, a power supply; 211, a gas source; 212, a vacuum pump; 213, substrate; and 214, a tray.

The vacuum vessel 201 includes a metallic member of SUS or Al or the like and is evacuated by the vacuum pump 212. The ultimate pressure of the vacuum vessels 201 is not particularly limited. The ultimate pressure is preferably not more than 1×10⁻³ Pa and more preferably not more than 1×10⁻⁴ Pa to reduce impurities mixed into the produced film and obtain high crystallinity. Moreover, it is desirable to prevent an increase in temperature of the wall surface of the vacuum vessel 201 by water cooling or the like.

The chamber shield 202 and rotary shutter 203 are each formed of a metallic member of SUS or Al or the like. However, the chamber shield 202 and rotary shutter 203 tend to be hot because of radiation heat from the substrate holder 205. Accordingly, the chamber shield 202 and rotary shutter 203 need to be each formed of a material which cannot deform or discharge impurities when becoming hot. Moreover, the chamber shield 202 and/or rotary shutter 203 tend to have a large heat capacity and have a low ability of following changes in temperature of the substrate holder 205. In such a case, the radiation heat from the chamber shield 202 and/or rotary shutter 203 degrades the temperature stability of the substrate 213. Accordingly, it is desirable to reduce the radiation heat from the chamber shield 202 and/or rotary shutter 203 by cooling the chamber shield 202 and/or rotary shutter 203. Moreover, the temperature stability of the substrate can be improved also by heating the chamber shield 202 and/or rotary shutter 203 to a comparatively stable temperature.

The substrate holder 205 includes a not-shown substrate heating mechanism and is capable of heating the substrate 213. The substrate holder 205 is connected to the up-down rotation mechanism 206. The up-down rotation mechanism 206 is capable of moving the substrate holder 205 up and down and rotating the substrate holder 205. By driving the up-down rotation mechanism 206, the substrate holder 205 is adjusted to such height and rotation speed that can implement a uniform thickness distribution.

The target 207 is connected to the cathode 208 though a not-shown bonding plate made of copper (Cu) or the like, and the cathode 208 is connected to the power supply 210. By driving the power supply 210, the target 207 is supplied with electric power for enabling sputtering. The cathode 208 is provided with a water-cooling mechanism for preventing an increase in temperature of the target and the magnet unit 209 for implementing magnetron sputtering. The kind of the power supply 210 is desirably a DC power supply from the perspective of cost but can be a DC pulse power supply or radio-frequency (RF) power supply.

FIGS. 2A and 2B illustrate double cathode-type sputtering apparatuses (reference numerals of the cathode, target, magnet unit, and power supply on one side are not shown). The sputtering apparatus may be a single cathode-type or two or more cathode-type. The single cathode-type can only deposit SrRuO₃ film, and two or more cathode-type can additionally form the base film. Moreover, in the two or more cathode-type sputtering apparatus, the same type of targets can be attached to the plural cathodes for sputtering at the same time to increase the deposition rate.

The material of the target 207 is preferably SrRuO₃ but may be SrRuOₓ (X: a positive number less than 3) having missing oxygen atoms. Moreover, the target 207 may be a composite target made of strontium oxide (SrO) and ruthenium (Ru) or SrO and RuO₂.

The gas used in sputtering is preferably a gas mixture of inert gas such as argon (Ar) and oxygen gas. These gases are introduced into the vacuum vessel 201 from the gas source 211 through a not-shown mass-flow controller (MFC) with the flow rate thereof controlled. Each sputtering apparatus illustrated in FIGS. 2A and 2B includes only the single gas source 211 so as not to complicate the drawing. However, the number of gas sources is actually unnecessary to be one, and the inert gas source and oxygen gas source may be separately provided. In this case, the gases are individually supplied into the vacuum vessel 201 through a not shown MFC from each gas source so that the respective flow rates can be independently controlled. In the case of not using gas, the not-shown valve between the MFC and vacuum vessels 201 is closed to prevent the gas from being introduced into the vacuum vessel 201.

The vacuum pump 212 is connected to the vacuum vessel 201 through a not-shown gate valve. At the process of film deposition, the aforementioned gas is introduced as the opening of the gate valve is adjusted to control the pressure in the vacuum vessels 201 to a predetermined pressure.

The substrate 213 or tray 214 is directly placed on the holder 205 or placed apart from the holder 205 by a not-shown substrate or tray supporting mechanism. The tray 214 is used when the substrate has a small diameter. Plural substrates are placed on the tray for simultaneous deposition. Certainly, it is not necessary to use the tray when the substrate has a large diameter like a Si substrate.

The material of the substrate 213 needs to be properly set for each type of object devices. The material of the tray can include various types of metallic materials or ceramics materials which are resistant to heating at high temperature. When the tray 214 is conveyed with the substrate holder 205 at high temperature, the tray 214 can break by heat shock. It is therefore necessary to select a material resistant to heat shock for the tray 214.

Hereinafter, a description is given of an example of the method of forming SrRuO₃ film using the sputtering apparatus according to the embodiment of the present invention with reference to FIGS. 2A and 2B. In the example described herein, the target 207 is a SrRuO₃ target. The target can be a SrRuOₓ target having missing oxygen atoms.

First, the substrate 213 (including the tray 214 in the case of a small-diameter substrate) is placed on the substrate holder 205, and the height and rotation speed of the substrate holder 205 are adjusted so that the thickness distribution of SrRuO₃ film is uniform. Thereafter, the not-shown substrate heating mechanism incorporated in the substrate holder 205 is turned on to adjust the substrate temperature to a predetermined deposition temperature. The predetermined deposition temperature is preferably a temperature of 450° C. or higher, and the deposition temperature of lower than 450° C. is not preferable because the SrRuO₃ film is hardly crystallized at the temperature. Moreover, the temperature of the substrate holder 205 in the process of conveying the substrate 213 does not need to be room temperature and maybe previously set to such a holder temperature that can implement the predetermined deposition temperature by previously turning on the not-shown substrate heating mechanism incorporated in the substrate holder 205. Using the above method is desirable because the time taken to raise the temperature of the substrate 213 can be shortened to lead to an increase in productivity.

Next, inert gas and oxygen gas are introduced from the inert gas source 211 to the vacuum vessel 201 through a not-shown MFC with the flow rate controlled. Furthermore, the opening of the not-shown gate valve between the vacuum pump 212 and the vacuum vessel 201 is adjusted to control the pressure of the oxygen-containing atmosphere in the vacuum vessel 201 to a predetermined pressure. The predetermined pressure in this process is preferably 1.0 Pa or more and less than 8.0 Pa. When the pressure of the oxygen-containing atmosphere is less than 1.0 Pa, the obtained SrRuO₃ film does not have good crystallinity, and when not less than 8.0 Pa, abnormal discharge is more likely to occur, which is not preferable. The predetermined pressure is more preferably 1.5 Pa or more and less than 5.0 Pa and most preferably 2.0 Pa or more and less than 3.0 Pa.

The gas mixture ratio of inert gas and oxygen gas introduced from the inert gas source 211 to the vacuum vessel 201 is not particularly limited, and the ratio (the flow rate ratio) of oxygen gas can be an arbitrary value in a range of 0 to 100%. However, when the oxygen gas ratio is 0%, oxygen atoms in the SrRuO₃ film are a little more likely to be missing, and the crystal quality thereof tends to be low. It is therefore preferable that the oxygen gas concentration is higher than 0%. When the oxygen gas ratio is 50% or higher, the deposition rate is extremely low. It is therefore preferable that the oxygen gas concentration is less than 50% when the apparatus is used in production.

Next, the rotation mechanism 204 is driven to allocate the aforementioned non-opening portion of the rotary shutter 203 to the target 207 composed of a SrRuO₃ target. Thereafter, electric power is supplied from the power supply 210 to the target 207 through the cathode 208 to generate plasma between the target 207 and the aforementioned non-opening portion. The target 207 is pre-sputtered by the generated plasma, and the surface of the target 207 is cleaned. Moreover, the sputtered particles ejected adhere to the non-opening portion. Most preferably, the electric power supplied herein is DC power. This is because many power supplies for other types of electric power are expensive and require another special apparatus configuration. In the case of using RF power, for example, a matching box is required. Use of the other types of electric power therefore tends to increase the apparatus cost. However, the effect of the present invention can be obtained even when RF power or DC pulse power is used, and the supplied power is not essentially DC power.

Next, the rotation mechanism 204 is driven to allocate the aforementioned opening portion of the rotary shutter 203 to the target 207 composed of a SrRuO₃ target, and deposition by sputtering is started. The sputtered particles ejected from the target reach the substrate 213 through the opening portion, thus forming SrRuO₃ film.

By using the thus-configured apparatus and process, it is possible to obtain a high-quality SrRuO₃ film at a high deposition rate while preventing abnormal discharge.

Hereinabove, in the embodiment of the present invention, the SrRuO₃ film deposition apparatus for illustrated in FIG. 1 and the offset rotary deposition-type magnetron sputtering apparatuses for depositing SrRuO₃ film (which are illustrated in FIGS. 2A and 2B) form SrRuO₃ film with a pressure of 1.0 Pa or more and less than 8.0 Pa as introducing oxygen gas. Accordingly, it is also possible to obtain high-quality SrRuO₃ film at a high deposition rate while preventing abnormal discharge in the case of using DC magnetron sputtering. Moreover, SrRuO₃ film can be manufactured at high productivity including the pretreatment before deposition of SrRuO₃ film.

### EXAMPLES

As a first example of the present invention, a description is given of examples of SrRuO₃ film formed on SrTiO₃(001) substrates.

SrRuO₃ film was formed on SrTiO₃(001) substrates by the offset rotary deposition-type DC magnetron sputtering using the deposition apparatus illustrated in FIG. 1. The inclined rotary deposition-type magnetron spattering apparatus illustrated in FIG. 2B was used as the sputtering chamber 104 illustrated in FIG. 1, and the treatment of each process was performed under the following conditions. In the pretreatment chamber 103, the substrate temperature was increased to 650° C. in oxygen gas for pre-heating.

Processing apparatus: inclined rotary deposition-type Magnetron sputtering apparatus
Ultimate pressure: 2×10⁻⁵ Pa
Substrate: 2-inch SrTiO₃(001)
Tray: inconel tray for conveying the 2-inch substrate
Target material: sintered SrRuOₓ target
Target size: 110 mm in diameter (circular shape), 5 mm thick
Target density: 90%
Vertical distance between the target center and substrate: 160 mm
Process gas: Ar/O₂ mixed gas
O₂ gas ratio in process: 4%
Power supply for sputtering: DC power supply
Process Power Input: 350 W
Process pressure: 0.5-300 Pa
Process temperature: 600° C.
Deposition time: 1800 seconds

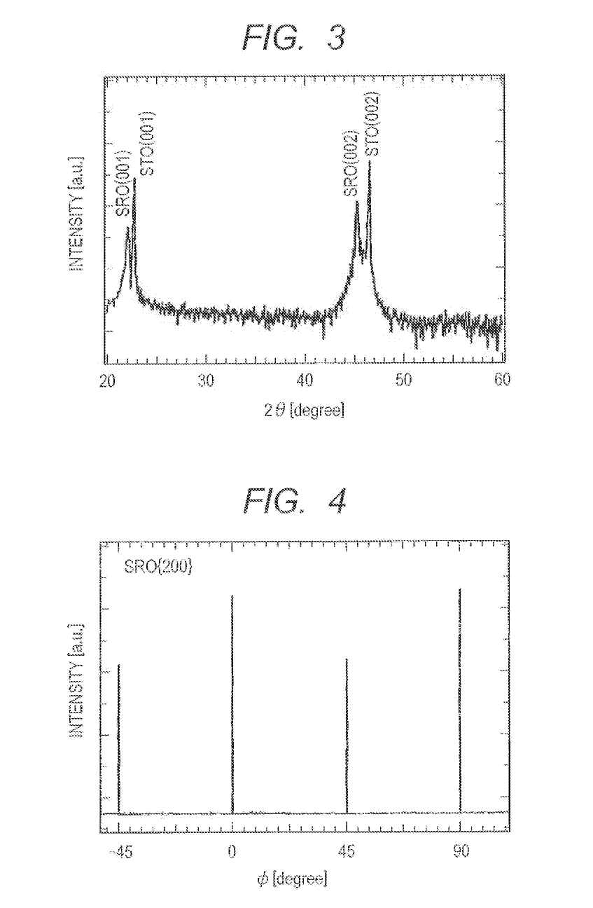

FIGS. 3, 4, and 5 are evaluation results using an X-ray diffraction (XRD) apparatus for the crystallinity of SrRuO₃ film manufactured under the aforementioned conditions (the deposition pressure was 2.5 Pa). In the diagrams, STO means SrTiO₃, and SRO means SrRuO₃. As crystal systems of SrRuO₃, there are known three types of systems: cubic system, tetragonal system, and orthorhombic system. However, it is very difficult to distinguish those systems from each other. Moreover, there will be no significant problem in many cases even if the systems of SrRuO₃ film are treated as the cubic system. Accordingly, SrRuO₃ is assumed to be of the cubic system in this specification.

FIG. 3 shows the evaluation result of the SrRuO₃ film by XRD measurement of 2θ/ω scan mode at symmetric reflection positions (the positions for observing the plane parallel to the substrate surface). The diffraction peaks at 2θ of 22.75° and 46.45° are diffraction peaks of (001) plane and (002) plane of SrTiO₃. The diffraction peaks at 2θ of 22.15° and 45.25° are diffraction peaks of (001) plane and (002) plane of SrRuO₃. In the XRD measurement with 2θ/ω scan mode at the symmetric reflection position, SrRuO₃ film has only the diffraction peaks of (001) plane and (002) plane. This reveals that the obtained SrRuO₃ film is c-axis oriented.

FIG. 4 shows the evaluation results of the SrRuO₃ film by XRD measurement with φ scan mode at In-plane positions (the positions for observing a lattice plane vertical to the substrate surface). The lattice plane used for the measurement is SrRuO₃{200}. {200} refers to (200) plane and equivalent planes thereof including (−220), (−2-20), and (2-20). In the measurement with φ scan mode, four sharp peaks are observed at intervals of 90 degrees in such a manner. This reveals that the SrRuO₃ film is epitaxially grown. Moreover, it is confirmed that the in-plane orientation relationship with SrTiO₃ was SrRuO₃(100)//SrTiO₃(100).

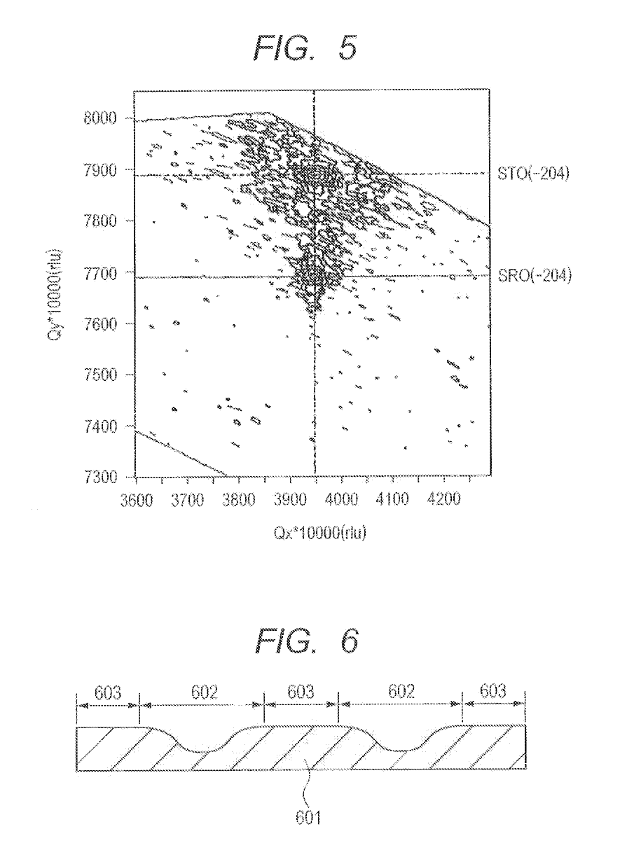

FIG. 5 shows the evaluation results of the SrRuO₃ film by XRD reciprocal lattice mapping measurement. In the measurement, SrTiO₃ film and SrRuO₃ film were measured in terms of reciprocal lattice space around (−204) plane. For (−204) plane of SrTiO₃ film and (−204) plane of SrRuO₃ film are observed on the same Qx coordinate in the reciprocal lattice space, it can be confirmed that the SrRuO₃ film is grown coherently on the SrTiO₃ film.

As described above, it is confirmed that the SrRuO₃ film formed under the aforementioned conditions (the deposition pressure is 2.5 Pa) had very good crystallinity. The deposition rate of the SrRuO₃ film in this process was 60 nm/h which was a deposition rate sufficiently satisfying the preferable deposition rate (not less than 10 nm/h) for the normal static target-facing type sputtering described in Patent Document 1. Furthermore, the same experiments were performed with the deposition pressure varied in a range of 0.5 Pa or more and less than 300 Pa. It was then confirmed that epitaxial film excellent in crystallinity was obtained when the deposition pressure was 1.0 Pa or more.

On the other hand, in the experiments with the deposition pressure set less than 8.0 Pa, no abnormal discharge occurred. In the experiments with the deposition pressure set to 8.0 Pa or more, abnormal discharge was more likely to occur, and it is confirmed that many particles existed on the surface of the SrRuO₃ film deposited. In order to investigate the cause of abnormal discharge, the inventors also performed observation and evaluation of the target after abnormal discharge occurred.

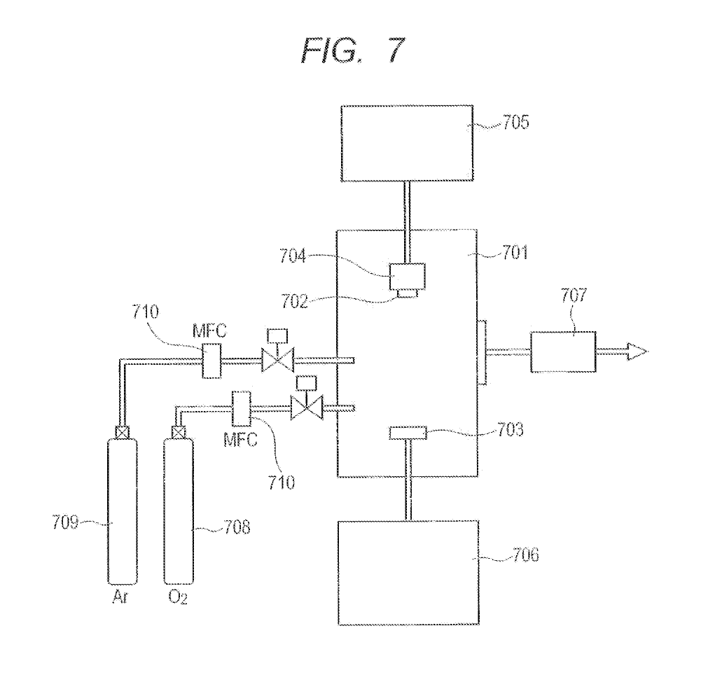

FIG. 6 is a view illustrating a cross-sectional profile of a SrRuO₃ target after occurrence of abnormal discharge. In the drawing, reference numeral 601 indicates a SrRuO₃ target; 602, erosion portions; and 603, non-erosion portions. The erosion portions 602 are regions in front of which comparatively high-density plasma was formed during the deposition by the magnetic field applied from the magnet unit in the magnetron sputtering, and in which the sputtering phenomenon progressed due to the formed plasma. Accordingly, the erosion portions 602 got deeper as the integrated electricity increases during the deposition. On the other hand, in the non-erosion portions 603, the sputtering phenomenon did not progress so much during the deposition because the plasma density was low in front of the non-erosion portions 603.

In FIG. 6, in the surface of the SrRuO₃ target 601 after occurrence of abnormal discharge, it is confirmed that only the erosion portions 602 are smooth and the non-erosion portions 603 include countless fine bores like craters. Moreover, the situations around the target were checked from a viewing port of the sputtering apparatus used in this embodiment. It is then confirmed that countless sparking particles were ejected from the target surface in the event of abnormal discharge. In other words, the fine bores are considered to be formed by the abnormal discharge and are considered to be formed only in the non-erosion portions 603.

The inventors therefore performed a composition analysis for the surfaces of the non-erosion portions 603. This reveals that the surfaces of the non-erosion portions 603 contained excess Sr. Sr is an easily-oxidizable material. Accordingly, it is unlikely that metallic Sr stably exists on the SrRuO₃ target 601 during the sputtering process in the oxygen-containing atmosphere, and Sr is considered to exist in the form of insulating SrO.

Accordingly, the causes of the aforementioned abnormal discharge can be inferred to be the following factors. Specifically, when the SrRuO₃ target 601 is sputtered, sputtered particles are ejected mainly from the erosion portion 602, and some of the particles are ejected as insulating SrO and reattach to the non-erosion portions 603. Alternatively, it is considered that some of the sputtered particles are ejected as metallic Sr, reattach to the non-erosion portions 603, and are then oxidized by oxygen contained in the atmosphere to form insulating SrO. Since insulating SrO is formed in the surfaces of the non-erosion portions 603 in such a manner, the SrO is thought to charge up during the process of DC sputtering and eventually cause insulation breakdown to reach abnormal discharge. The reason why abnormal discharge is less likely to occur when the deposition pressure is less than 8.0 Pa is still unknown.

As described above, by using the offset rotary deposition-type magnetron sputtering apparatus illustrated in FIGS. 2A and 2B under the deposition conditions including: oxygen-containing atmosphere and a deposition pressure of 1.0 Pa or more and less than 8.0 Pa, it is possible to obtain high-quality SrRuO₃ film at a high deposition rate while preventing occurrence of abnormal discharge.

### COMPARATIVE EXAMPLE

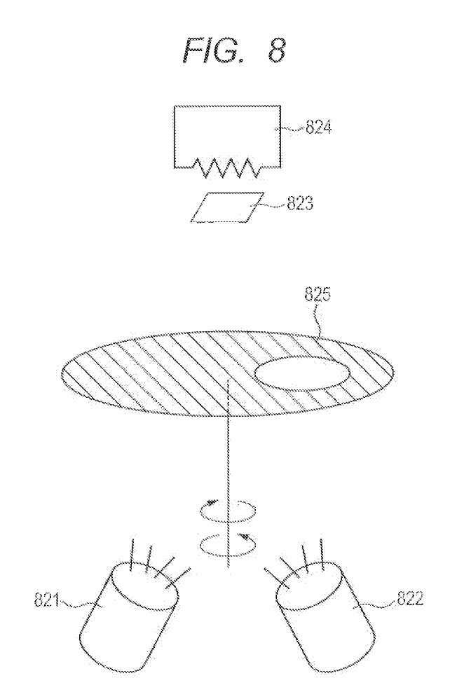

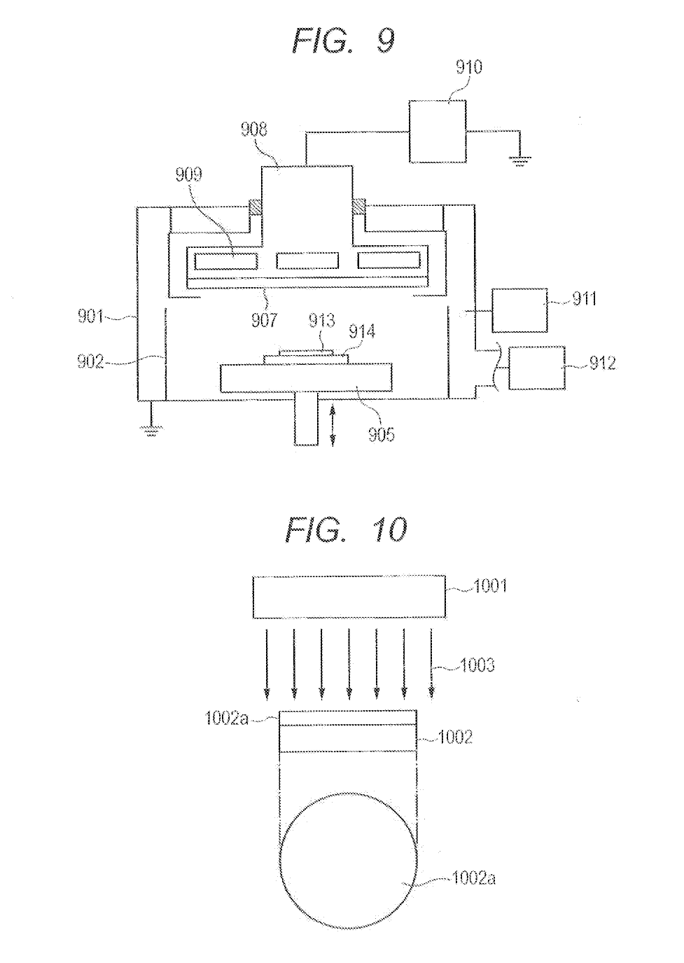

As a comparative example for the present invention, SrRuO₃ film was formed under the same conditions as those of Example by using the normal static target-facing type magnetron sputtering apparatus illustrated in FIG. 7.

As a result, when the deposition pressure was set to 8.0 Pa or more, high-quality SrRuO₃ film was obtained, but it became clear that it was difficult to prevent occurrence of abnormal discharge. On the other hand, when the deposition pressure was set less than 8.0 Pa, occurrence of abnormal discharge was prevented, but it became clear that it was difficult to obtain high-quality SrRuO₃ film.

In this comparative example, the abnormal discharge that occurred at a deposition pressure of 8.0 Pa or more is inferred to be caused by the aforementioned reattachment of SrO to the non-erosion portions. Moreover, when the deposition pressure was set less than 8.0 Pa, it is thought to be difficult to obtain high-quality SrRuO₃ film because of damage due to high-energy particles as described in Patent Document 1.

Even when the deposition pressure was not less than 8.0 Pa, the probability of abnormal discharge was reduced by reducing the process power input to about 50 W, but it was simultaneously revealed that the deposition rate was significantly reduced and the productivity was lowered.

Accordingly, the offset rotary deposition-type DC magnetron sputtering can provide high-quality SrRuO₃ film at a high deposition rate while preventing occurrence of abnormal discharge by using the oxygen-containing atmosphere and a deposition pressure of 1.0 Pa or more and less than 8.0 Pa as the deposition conditions. On the other hand, in the normal static target-facing type sputtering, it is difficult to obtain high-quality SrRuO₃ film when the deposition pressure is 1.0 Pa or more and less than 8.0 Pa, and it is difficult to prevent the occurrence of abnormal discharge while implementing a high deposition rate when the deposition pressure is 8.0 Pa or more.

The first factor that can provide a high deposition rate in the offset rotary deposition-type DC magnetron sputtering according to the present invention which is comparable to that of the normal static target-facing type sputtering described in Patent Document 1 is that deposition can be performed with a comparatively low pressure of 1.0 Pa or more and less than 8.0 Pa, with which the normal static target-facing type sputtering can hardly provide high-quality SrRuO₃ film. To be specific, for the deposition pressure can be set lower than that of the normal static target-facing type sputtering, it is thought that dispersion due to gas particles, of sputtered particles ejected from the target is reduced to increase the sputtered particles reaching the substrate and thereby implement a high deposition rate.

A description is given of “it is possible to form SrRuO₃ film with a comparatively low pressure of 1.0 Pa or more and less than 8.0 Pa with which high-quality SrRuO₃ film cannot be obtained by the normal static target-facing type sputtering” in the present invention as described above.

FIG. 10 is a view illustrating the situation of the normal static target-facing type sputtering described in Patent Document 1. In FIG. 10, a target 1001 and a substrate 1002 are located so as to face each other, and the substrate 1002 remains stationary. In FIG. 10, in general, the substrate 1002 is rectangular when the target 1001 is circular, and the substrate 1002 is circular when the target 1001 is rectangular. However, the target 1001 can be circular when the substrate 1002 is rectangular, and the target 1001 can be rectangular when the substrate 1002 is circular.

Generally, it is considered that the substrate is most likely to be damaged when high-energy particles generated by sputtering the target are incident on the substrate vertically. In the case of the static target-facing type sputtering illustrated in FIG. 10, the target 1001 is located to face the substrate 1002. The substrate 1002 is therefore covered with the target 1001 and is more likely to be always irradiated with high-energy particles 1003 which are vertically incident on the substrate 1002. Accordingly, damage is accumulated all over the entire processed surface of the substrate 1002. Reference numeral 1002a indicates a region where damages due to the high-energy particles are accumulated in the substrate 1002. In Patent Document 1, by setting the deposition pressure to 8.0 Pa or more to disperse the high-energy particles, the acceleration of the high-energy particles is reduced, thereby reducing damage. Conversely, when the deposition pressure is set lower than 8.0 Pa in the static target-facing type sputtering illustrated in FIG. 10 as disclosed in Patent Document 1, the effect on reducing the acceleration of the high-energy particles 1003 is reduced, and the high-damage accumulated region 1002a is formed in the substrate 1002.

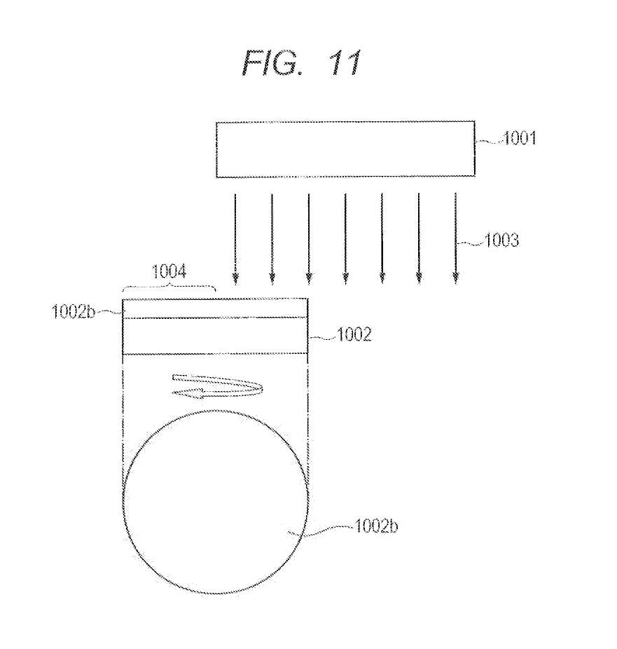

On the other hand, the embodiment of the present invention employs the following method as illustrated in FIG. 2A as an example: the center of the substrate (the center of the substrate holder) is offset from the center of the target, that is, the target and substrate are arranged so that when the target is projected onto the substrate, the substrate includes a region where the projected image of the target is not formed; and the substrate is rotated about the normal direction of the processed surface (offset rotary deposition). Accordingly, at a certain moment during the deposition, the substrate includes a region where high-energy particles vertically incident onto the substrate are not incident (namely, the region where the aforementioned projected image is not formed). To be specific, as illustrated in FIG. 11 (corresponding to the offset arrangement illustrated in FIG. 2A), a region 1004 which is not exposed to high-energy particles 1003 vertically incident onto the substrate 1002 can be formed in the substrate 1002 at a certain moment. In FIG. 11, since the substrate 1002 rotates about the normal direction of the processed surface of the substrate, a region which is not always exposed to the high-energy particles vertically incident onto the substrate can be formed in the processed surface. It is therefore possible to reduce damage to the substrate due to high-energy particles. In other words, the processed surface of the substrate 1002 is a damage region 1002b with less damaged.

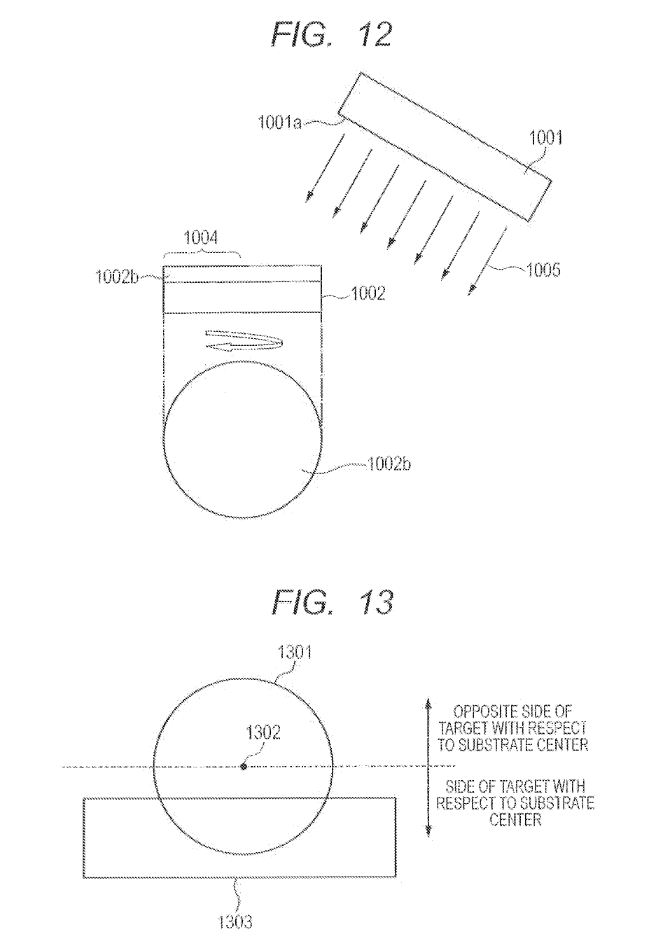

As illustrated in FIG. 2B, another example of the embodiment of the present invention employs a method in which the center of the substrate (the center of the substrate holder) is offset from the center of the inclined target and the substrate is rotated about the normal direction of the processed surface of the substrate (offset rotary deposition). In this method, the target and the substrate are arranged so that when the target is projected onto the substrate, the substrate includes a region where the projected image of the target is not formed. Accordingly, the region where high-energy particles 1005 propagating in the normal direction of a sputtered surface 1001a of the target 1001 are not incident (namely, the region where the aforementioned projected image is not formed) can be formed in the substrate at a certain moment during the deposition. In other words, as illustrated in FIG. 12 (corresponding to the offset position illustrated in FIG. 2B), a region 1004 which is not exposed to the high-energy particles 1005 progressing in the normal direction of the sputtered surface 1001a can be formed in the substrate 1002 at a certain moment. In FIG. 12, since the substrate 1002 rotates about the normal direction of the processed surface of the substrate, the region which is not always exposed to the high-energy particles propagating in the normal direction of a sputtered surface 1001a can be formed in the processed surface. It is therefore possible to reduce the damage to the substrate due to the high energy particles. In other words, the processed surface of the substrate 1002 is a damage region 1002b less damaged.

As the aforementioned offset position, it is preferable that the target and substrate are arranged so that the aforementioned projected image is not formed on the opposite side of the center of the substrate from the target. To be specific, as illustrated in FIG. 13, it is preferable that the target and substrate are arranged so that a projected image 1303 of the target is formed on the target side of a center 1302 of a substrate 1301. In this arrangement, at the film deposition for the rotated substrate, it is possible to eliminate the region always exposed to the high-energy particles 1003 and 1005 which are most likely to cause damage in the present invention. It is more preferable that the projected image of the target is not formed on the substrate. This arrangement can prevent the entire surface of the processed surface of the substrate from not being exposed to the high-energy particles 1003 and 1005, thus minimizing the damage.

As described above, by the offset rotary deposition, it is possible to reduce damage to the substrate without reducing the acceleration of high-energy particles. Specifically, it is possible to reduce damage to SrRuO₃ even if the deposition pressure is set comparatively low as less than 8.0 Pa.

The second factor that implements a high deposition rate comparable to that of the normal static target-facing type sputtering described in Patent Document 1 is that by using the aforementioned comparatively low pressure, abnormal discharge is less likely to occur and the process power input can be increased. Specifically, the normal static target-facing type sputtering needs a deposition pressure of 8.0 Pa or more to provide high-quality SrRuO₃ film. However, if DC magnetron sputtering is used with such a high pressure, abnormal discharge is more likely to occur. To reduce the occurrence of abnormal discharge, it is necessary to reduce the process power input, and this makes it difficult to implement a high deposition rate. On the other hand, by the offset rotary deposition-type DC magnetron sputtering according to the present invention, high-quality SrRuO₃ film can be easily obtained at a comparatively low pressure of 1.0 Pa or more and less than 8.0 Pa, and abnormal discharge is less likely to occur under such a comparatively low pressure. It is therefore considered that the power input can be increased and the high deposition rate is thereby implemented.

Because of the aforementioned reasons, it can be thought that the offset rotary deposition-type magnetron sputtering, which is generally disadvantageous in terms of the deposition rate compared to the normal static target-facing type sputtering, can achieve a high deposition rate which is comparable to that of the normal static target-facing type sputtering.

1. A SrRuO₃ film deposition method by offset rotary deposition-type DC magnetron sputtering, the method comprising:
depositing a SrRuO₃ film on a substrate at a deposition pressure of 1.0 Pa or more and less than 8.0 Pa in an oxygen-containing atmosphere.

2. The SrRuO₃ film deposition method according to claim 1, wherein
a deposition pressure is 1.5 Pa or more and less than 5.0 Pa.

3. The SrRuO₃ film deposition method according to claim 1, wherein
the deposition pressure is 2.0 Pa or more and less than 3.0 Pa.

4. The SrRuO₃ film deposition method according to claim 1, wherein
the DC magnetron sputtering uses, as the target, any one of a SrRuO₃ target and an oxygen-deficient SrRuO₂ target (x is a positive number less than 3).

5. The SrRuO₃ film deposition method according to claim 1, wherein the substrate is any one of a Si substrate and a SrTiO₃ substrate.

6. The SrRuO₃ film deposition method according to claim 5, wherein
the substrate is a SrTiO₃ substrate, and
pre-heating of heating the SrTiO₃ substrate to 500° C. or higher is performed before the SrRuO₃ film is deposited on the SrTiO₃ substrate.

7. The SrRuO₃ film deposition method according to claim 6, wherein the pre-heating is performed in an O₂ gas atmosphere.

8. The SrRuO₃ film deposition method according to claim 1, wherein
the substrate is a SrTiO₃ substrate, and
a SrTiO₃ film is homoepitaxially grown on the SrTiO₃ substrate before the SrRuO₃ film is deposited on the SrTiO₃ substrate.

9. The SrRuO₃ film deposition method according to claim 8, wherein pre-heating of heating the SrTiO₃ substrate to 500° C. or higher is performed before the SrTiO₃ film is homoepitaxially grown on the SrTiO₃ substrate.

10. The SrRuO₃ film deposition method according to claim 9, wherein the pre-heating is performed in an O₂ gas atmosphere.

11. The SrRuO₃ film deposition method according to claim 5, wherein
the substrate is a Si substrate, and
pre-heating of heating the Si substrate to 850° C. or higher in vacuum is performed before the SrRuO₃ film is deposited on the Si substrate.

12. The SrRuO₃ film deposition method according to claim 5, wherein
the substrate is a Si substrate, and
an oxide film on the Si substrate is removed with active gas before the SrRuO₃ film is deposited on the Si substrate.

13. The SrRuO₃ film deposition method according to claim 5, wherein
the substrate is a Si substrate, and
the Si substrate is heated in an oxygen-containing atmosphere before the SrRuO₃ film is deposited on the Si substrate.

14. The SrRuO₃ film deposition method according to claim 5, wherein
the substrate is a Si substrate, and
in the case of depositing the SrRuO₃ film on the Si substrate, a material different from materials for the SrRuO₃ film and the Si substrate is formed as an underlayer for the SrRuO₃ film between the SrRuO₃ film and the Si substrate.

15. The SrRuO₃ film deposition method according to claim 14, wherein the underlayer is made of any one of Ti, Pt, and SrTiO₃.

16. The SrRuO₃ film deposition method according to claim 15, wherein the underlayer is formed by any one of vacuum deposition, sputtering, MOCVD, and MBE.

17. The SrRuO₃ film deposition method according to claim 1, wherein
the substrate is conveyed from a conveyance chamber provided with a conveyance robot configured to convey the substrate, to a sputtering chamber provided on a periphery of the conveyance chamber, and
the SrRuO₃ film is then deposited in the sputtering chamber.

18. The SrRuO₃ film deposition method according to claim 17, wherein at least a part of pretreatment to be performed on the substrate before the deposition of the SrRuO₃ film is performed in a pretreatment chamber provided on the periphery of the conveyance chamber.

19. The SrRuO₃ film deposition method according to claim 17, wherein pretreatment to be performed on the substrate before the deposition of the SrRuO₃ film is performed in the sputtering chamber.
